(19) United States
(12) Patent Application Publication
(10) Pub. No.: US 2024/0074085 A1
(43) Pub. Date: Feb. 29, 2024

(54) Set And Removed Server Device Detection System And Method Thereof

(71) Applicants: lnventec (Pudong) Technology Corporation, Shanghai (TW); lnventec Corporation, Taipei City (TW)

(72) Inventor: Xing-Xing He, Shanghai (CN)

(21) Appl. No.: 17/945,846

(22) Filed: Sep. 15, 2022

(30) Foreign Application Priority Data
Aug. 29, 2022 (CN) 202211042087.X

(51) Int. Cl. H05K 7/14; G06F 11/22

(52) U.S. Cl. CPC H05K 7/1492; G06F 11/2247; H05K 7/1498

(57) ABSTRACT

A set and removed server device detection system and a method thereof are disclosed, a testing device obtains a MAC address corresponding to a network connection interface of one of server setting spaces from a rack and a value of current of a power supply interface of the one of server setting spaces from a power management system, and the testing device determines whether the server device is set in or removed from the rack, to establish a test work to test a server device and then delete the test work based on whether the value of the current is a null value, whether the MAC address is a null value, and whether the testing device is linked to a board management controller of the server device, and based on a test status of the server device.

### CROSS-REFERENCE TO RELATED APPLICATION

This application claims the benefit of Chinese Application Serial No. 202211042087.X, filed Aug. 29, 2022, which is hereby incorporated herein by reference in its entirety.

### BACKGROUND OF THE INVENTION

### 1. Field of the Invention

The present invention relates to a setting determination system and a method thereof, and more particularly to a set and removed server device detection system which enables a testing device to determine whether a server device is set in a server setting space, and establish a test work based on the determining result to test the server device and then delete the test work, and a method thereof.

### 2. Description of the Related Art

In recent years, testing a server device set in a rack requires a tester to set a test work in a testing device, so that t the testing device is able to check, on a display interface, whether the server device is set in the corresponding server setting space in a rack. However, after the server device is tested completely and the server device is removed from the rack, it is hard to delete the corresponding test work in the testing device automatically. The above-mentioned situations are the conventional problems in testing the server device set in the rack.

According to above-mentioned contents, what is needed is to develop an improved solution to solve the conventional problem that the existing testing device is unable to automatically establish and delete a test work for testing the server device set in the server device based on whether the server device is set in or removed from the rack.

### SUMMARY OF THE INVENTION

An objective of the present invention is to provide a set and removed server device detection system and a method thereof to solve the problem that the existing testing device is unable to automatically establish and delete a test work for testing the server device set in the server device based on whether the server device is set in or removed from the rack.

In order to achieve the objective, the present invention provides a set and removed server device detection system including a rack, a power management system and a testing device. The rack has layers of rack accommodation spaces, power supply interfaces and network connection interfaces, wherein each of the layers of rack accommodation spaces includes server setting spaces, one of the power supply interfaces and one of network connection interfaces are disposed in one of the server setting spaces, and the rack is configured to provide a MAC address of one of the network connection interfaces. The power management system includes power suppliers, wherein each of the power suppliers is configured to supply power to the power supply interfaces in the server setting spaces of one of the layers of rack accommodation spaces in the rack, and the power management system is configured to provide current to the power supply interfaces. The testing device is linked to the rack and the power management system, and configured to obtain the MAC addresses of the network connection interfaces from the rack, and obtain values of the currents of the power supply interfaces from the power management system, wherein the testing device is operative to determine that a server device is set in one of the server setting spaces when the value of the current of the power supply interface corresponding to the one of the server setting spaces is not a null value and the MAC address of the network connection interface corresponding to the one of the server setting space is not the null value; establish a test work to test the server device set in the one of the server setting spaces; determine that the server device is removed from the one of the server setting spaces and delete the test work when a test status of the server device set in the one of the server setting spaces is a successful status, or an error status and the testing device fails to communicate with the board management controller of the server device; determine that the server device is removed from the one of the server setting space, end and delete the test work when the test status of the server device set in the one of the server setting space is a test tool exception, a test time of a test tool being timed out, or failure in communication with a board management controller of the server device, and the value of the current of the power supply interface corresponding to the one of the server setting spaces is the null value.

In order to achieve the objective, the present invention provides a set and removed server device detection method including steps of: providing a rack having layers of rack accommodation spaces, power supply interfaces and network connection interfaces, wherein each of the layers of rack accommodation spaces comprises server setting spaces, one of the power supply interfaces and one of network connection interfaces are disposed in one of the server setting spaces, and the rack is configured to provide a MAC address of one of the network connection interfaces; providing a power management system comprising power suppliers, wherein each of the power suppliers is configured to supply power to the power supply interfaces in the server setting spaces in one of the layers of rack accommodation space in the rack, the power management system is configured to provide current to one of the power supply interfaces; linking a testing device to the rack and the power management system; obtaining the MAC addresses of the network connection interfaces from the rack, and obtaining values of currents of the power supply interfaces from the power management system, by the testing device; wherein the testing device is operative to: determine that a server device is set in one of the server setting spaces when the value of the current of the power supply interface corresponding to the one of the server setting spaces is not a null value and the MAC address of the network connection interface corresponding to the one of the server setting space is not the null value; establish a test work to test the server device set in the one of the server setting spaces; determine that the server device is removed from the one of the server setting spaces and delete the test work when a test status of the server device set in the one of the server setting spaces is a successful status, or an error status and the testing device fails to communicate with the board management controller of the server device; determine that the server device is removed from the one of the server setting space, end and delete the test work when the test status of the server device set in the one of the server setting space is a test tool exception, a test time of a test tool being timed out, or failure in communication with a board management controller of the server device, and the value of the current of the power supply interface corresponding to the one of the server setting spaces is the null value.

According to the above-mentioned system and method of the present invention, the difference between the present invention and the conventional technology is that the testing device obtains the MAC address corresponding to the network connection interface of one of server setting spaces from the rack and the value of the current of the power supply interface of the one of the server setting spaces from the power management system, and the testing device determines whether the server device is set in or removed from the rack, to establish the test work to test the server device and then delete the test work based on whether the value of the current is a null value, whether the MAC address is a null value, and whether the testing device is linked to the board management controller of the server device, and based on the test status of the server device.

Therefore, the above-mentioned solution of the present invention is able to achieve the technical effect of establishing or deleting the test work based on a detection for the server device, which is set or removed.

### BRIEF DESCRIPTION OF THE DRAWINGS

The structure, operating principle and effects of the present invention will be described in detail by way of various embodiments which are illustrated in the accompanying drawings.

FIG. 1 is a block diagram of a set and removed server device detection system of the present invention.

FIG. 2 is a schematic diagram of a rack applied in a set and removed server device detection system of the present invention.

FIG. 3 is a schematic diagram of a power management system applied in a set and removed server device detection system of the present invention.

FIG. 4 is a schematic diagram of a display interface applied in a set and removed server device detection system of the present invention.

FIGS. 5A and 5B are flowcharts of a set and removed server device detection method of the present invention.

### DETAILED DESCRIPTION OF THE PREFERRED EMBODIMENTS

The following embodiments of the present invention are herein described in detail with reference to the accompanying drawings. These drawings show specific examples of the embodiments of the present invention. These embodiments are provided so that this disclosure will be thorough and complete, and will fully convey the scope of the invention to those skilled in the art. It is to be acknowledged that these embodiments are exemplary implementations and are not to be construed as limiting the scope of the present invention in any way. Further modifications to the disclosed embodiments, as well as other embodiments, are also included within the scope of the appended claims.

These embodiments are provided so that this disclosure is thorough and complete, and fully conveys the inventive concept to those skilled in the art. Regarding the drawings, the relative proportions and ratios of elements in the drawings may be exaggerated or diminished in size for the sake of clarity and convenience. Such arbitrary proportions are only illustrative and not limiting in any way. The same reference numbers are used in the drawings and description to refer to the same or like parts. As used herein, the singular forms “a”, “an” and “the” are intended to include the plural forms as well, unless the context clearly indicates otherwise.

It is to be acknowledged that, although the terms ‘first’, ‘second’, ‘third’, and so on, may be used herein to describe various elements, these elements should not be limited by these terms. These terms are used only for the purpose of distinguishing one component from another component. Thus, a first element discussed herein could be termed a second element without altering the description of the present disclosure. As used herein, the term “or” includes any and all combinations of one or more of the associated listed items.

It will be acknowledged that when an element or layer is referred to as being “on,” “connected to” or “coupled to” another element or layer, it can be directly on, connected or coupled to the other element or layer, or intervening elements or layers may be present. In contrast, when an element is referred to as being “directly on,” “directly connected to” or “directly coupled to” another element or layer, there are no intervening elements or layers present.

In addition, unless explicitly described to the contrary, the words “comprise” and “include”, and variations such as “comprises”, “comprising”, “includes”, or “including”, will be acknowledged to imply the inclusion of stated elements but not the exclusion of any other elements.

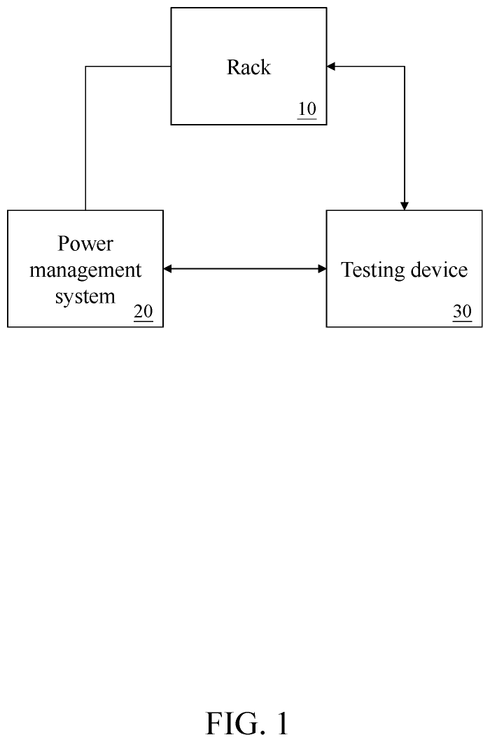

A set and removed server device detection system of the present invention will be described in the following paragraphs, and please refer to FIG. 1, which is a block diagram of a set and removed server device detection system of the present invention.

As shown in FIG. 1, the present invention provides a set and removed server device detection system including a rack 10, a power management system 20 and a testing device 30.

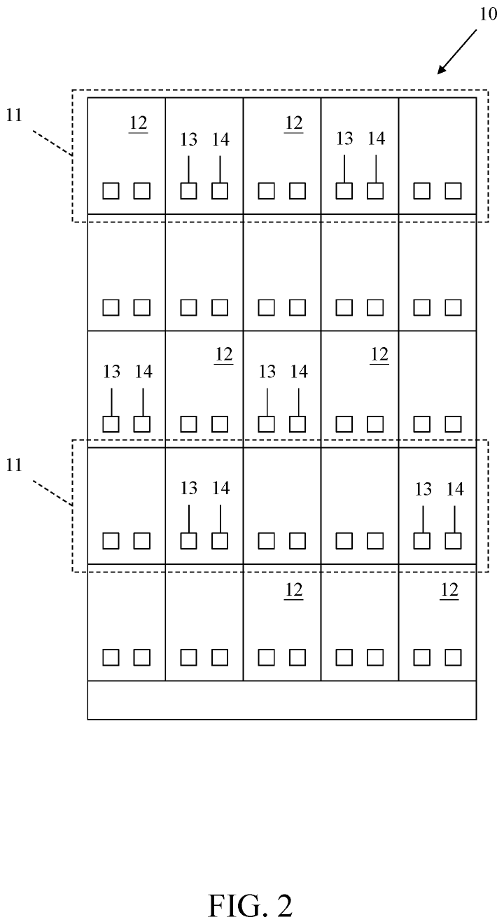

The rack 10 has layers of rack accommodation spaces 11, power supply interfaces 13 and network connection interfaces 14. Each of the layers of rack accommodation spaces includes server setting spaces, one of the power supply interfaces 13 and one of network connection interfaces 14 are disposed in one of the server setting spaces 12. The rack 10 is configured to provide a media access control (MAC) address of one of the network connection interfaces 14. Please refer to FIG. 2, which shows a schematic view of the rack 10 applied in the set and removed server device detection system of the present invention.

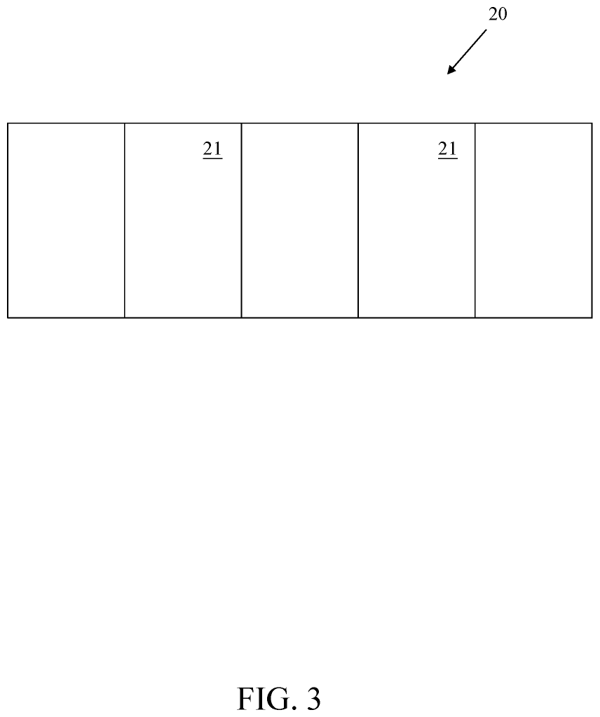

The power management system 20 includes power suppliers 21, each of the power supplier 21 is configured to supply power to the power supply interfaces 13 in the server setting spaces 12 in one of the layers of rack accommodation space 11 in the rack 10. The power management system 20 is configured to provide a current value to one of the power supply interface 13. Please refer to FIG. 3, which shows a schematic view of the power management system 20 applied in the set and removed server device detection system of the present invention.

The testing device 30 is linked to the rack 10 and the power management system 20, and configured to obtain the MAC address of one of the network connection interfaces 14 from the rack 10, and the value of the current of one of the power supply interfaces 13 from the power management system 20. It should be noted that the testing device 30 can periodically obtain MAC addresses of the network connection interfaces 14 from the rack 10, for example, every 30 seconds or 60 seconds; however, these examples are merely for exemplary illustration, and the application field of the present invention is not limited to these examples. The testing device 30 is operative to execute the following process.

When the value of the current of the power supply interface 13 corresponding to one of the server setting spaces 12 is not a null value and the MAC address of the network connection interface 14 corresponding to the one of the server setting spaces 12 is not a null value, the testing device 30 determines that the server device is set in the one of the server setting space 12.

Next, the testing device 30 establishes a test work to test the server device set in the one of the server setting spaces 12.

Next, when a test status of the server device set in the one of the server setting spaces 12 is a successful status, or an error status and the testing device 30 fails to communicate with a board management controller (BMC) of the server device, the testing device 30 determines that the server device is removed from the one of the server setting spaces 12 and then deletes the test work.

When the test status of the server device set in the one of server setting spaces 12 is a test tool exception, a test time of a test tool being timed out, failure in communication with the board management controller of the server device, and the value of the current of the power supply interface 13 corresponding to the server setting space 12 is a null value, the testing device 30 determines that the server device is removed from the one of the server setting spaces 12, and the testing device 30 ends the test work and delete the test work.

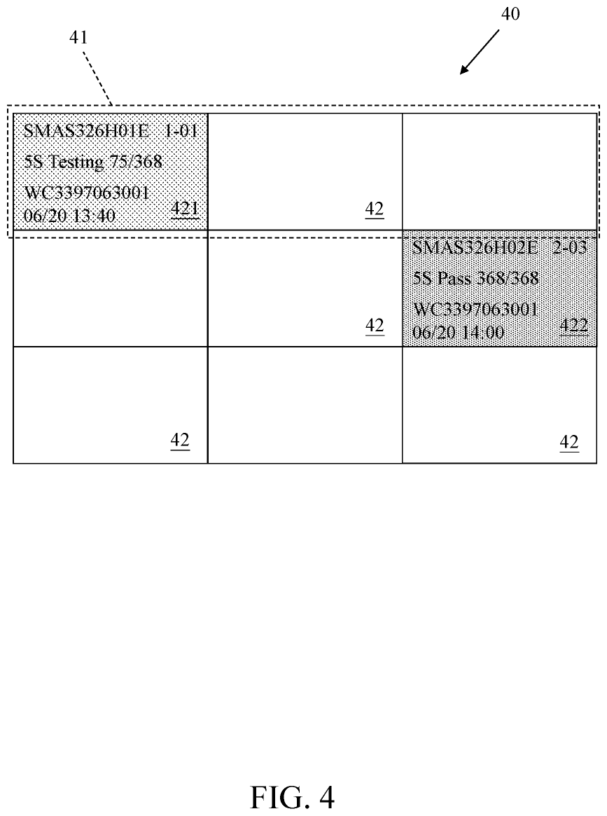

The testing device 30 displays the test status of the server device set in the one of the server setting space 12, on the display interface 40. Please refer to FIG. 4, which shows a schematic view of the display interface 40 in the set and removed server device detection system of the present invention. The display interface 40 is in a form of table, and in the table, each row 41 indicates a corresponding one of the layers of rack accommodation spaces 11, and each of data cells 42 in one of the rows 41 indicates one of the server setting spaces 12.

As shown in FIG. 4, a first data cell 421 shows a text “SMAS326H01E” as a test serial number, a text “1-01” as a location of the server setting space in the rack, a text “5S” as testing station information, a text “Testing” as a test status, a text “75/368” as a testing progress (that is, the testing station 5S must perform 368 testing tool tests, and now it is in progress to the 75th testing tool test), a text “WC3397063001” as a test mode, and a text “06/20 13:40” as test start date and time. It should be noted that, as shown in FIG. 4, the first data cell 421 is shown in a first presentation effect; for example, the first presentation effect can include a filling effect of different colors, a font flashing effect, different color fonts, but these examples are merely for exemplary illustration, and the application field of the present invention is not limited to these examples.

As shown in FIG. 4, a second data cell 422 shows a text “SMAS326H02E” as a test serial number, text “2-03” as a location of the server setting space in the rack, a text “5S” as testing station information, a text “pass” as a test status, a text “368/368” as a test progress (it indicates that testing station 5S must perform 368 testing tool tests and now all of the testing tool tests are completed), a text “WC3397063001” as a test mode, and a text “06/20 14:00” as test start date and time. It should be noted that, as shown in FIG. 4, the second data cell 422 is shown with a second presentation effect, and the second presentation effect and the first presentation effect are different from each other, for example, the second presentation effect can be the filling effect of different colors, a font flashing effect, different color fonts, these examples are merely for exemplary illustration, and the application field of the present invention is not limited to these examples.

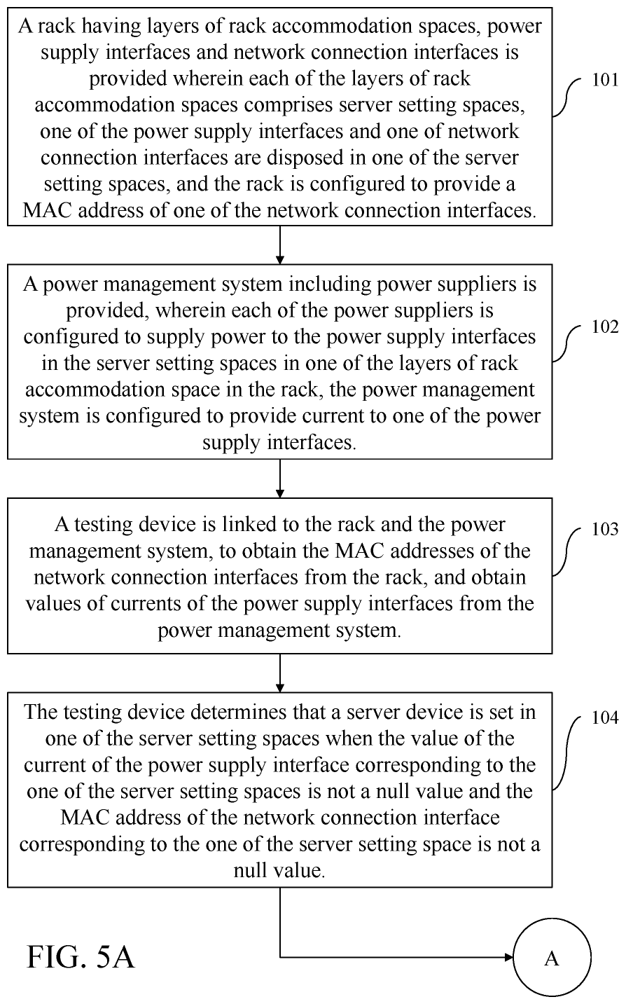

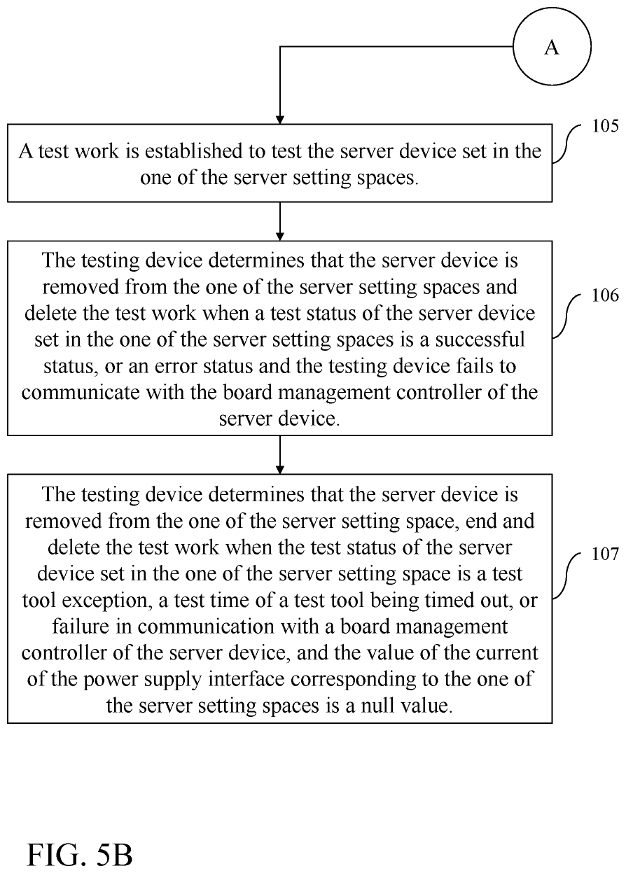

The operation of the method of the present invention will be described in the following paragraphs, and please refer to FIGS. 5A and 5B, which are flowcharts of a set and removed server device detection method of the present invention.

The present invention provides a set and removed server device detection method including the following steps.

In a step 101, a rack having layers of rack accommodation spaces, power supply interfaces and network connection interfaces is provided wherein each of the layers of rack accommodation spaces comprises server setting spaces, one of the power supply interfaces and one of network connection interfaces are disposed in one of the server setting spaces, and the rack is configured to provide a MAC address of one of the network connection interfaces. In a step 102, a power management system including power suppliers is provided, wherein each of the power suppliers is configured to supply power to the power supply interfaces in the server setting spaces in one of the layers of rack accommodation space in the rack, the power management system is configured to provide current to one of the power supply interfaces. In a step 103, a testing device is linked to the rack and the power management system, to obtain the MAC addresses of the network connection interfaces from the rack, and obtain values of currents of the power supply interfaces from the power management system.

In a step 104, the testing device determines that a server device is set in one of the server setting spaces when the value of the current of the power supply interface corresponding to the one of the server setting spaces is not a null value and the MAC address of the network connection interface corresponding to the one of the server setting space is not a null value. In a step 105, a test work is established to test the server device set in the one of the server setting spaces. In a step 106, the testing device determines that the server device is removed from the one of the server setting spaces and delete the test work when a test status of the server device set in the one of the server setting spaces is a successful status, or an error status and the testing device fails to communicate with the board management controller of the server device. In a step 107, the testing device determines that the server device is removed from the one of the server setting space, end and delete the test work when the test status of the server device set in the one of the server setting space is a test tool exception, a test time of a test tool being timed out, or failure in communication with a board management controller of the server device, and the value of the current of the power supply interface corresponding to the one of the server setting spaces is a null value.

According to above-mentioned contents, the difference between the present invention and the conventional technology is that, in the present invention, the testing device obtains the MAC address corresponding to the network connection interface of one of the server setting spaces from a rack and the value of the current of the power supply interface of the one of the server setting spaces from the power management system, and the testing device determines whether the server device is set in or removed from the rack, to establish the test work to test the server device and then delete the test work based on whether the value of the current is a null value, whether the MAC address is a null value, and whether the testing device is linked to the board management controller of the server device, and based on the test status of the server device.

Therefore, the above-mentioned technical solution of the present invention is able to solve the conventional problem that the existing testing device is unable to automatically establish and delete a test work for testing the server device set in the server device based on whether the server device is set in or removed from the rack, so as to achieve the technical effect of establishing or deleting the test work based on the detection for the server device, which is set or removed.

The present invention disclosed herein has been described by means of specific embodiments. However, numerous modifications, variations and enhancements can be made thereto by those skilled in the art without departing from the spirit and scope of the disclosure set forth in the claims.

What is claimed is:

1. A set and removed server device detection system, comprising:
a rack, having layers of rack accommodation spaces, power supply interfaces and network connection interfaces, wherein each of the layers of rack accommodation spaces comprises server setting spaces, one of the power supply interfaces and one of network connection interfaces are disposed in one of the server setting spaces, and the rack is configured to provide a MAC address of one of the network connection interfaces;
a power management system, comprising power suppliers, wherein each of the power suppliers is configured to supply power to the power supply interfaces in the server setting spaces of one of the layers of rack accommodation spaces in the rack, and the power management system is configured to provide current to the power supply interfaces;
a testing device, linked to the rack and the power management system, and configured to obtain the MAC addresses of the network connection interfaces from the rack, and obtain values of the currents of the power supply interfaces from the power management system, wherein the testing device is operative to:
determine that a server device is set in one of the server setting spaces when the value of the current of the power supply interface corresponding to the one of the server setting spaces is not a null value and the MAC address of the network connection interface corresponding to the one of the server setting space is not the null value;
establish a test work to test the server device set in the one of the server setting spaces;
determine that the server device is removed from the one of the server setting spaces and delete the test work when a test status of the server device set in the one of the server setting spaces is a successful status, or an error status and the testing device fails to communicate with the board management controller of the server device; and
determine that the server device is removed from the one of the server setting space, end and delete the test work when the test status of the server device set in the one of the server setting space is a test tool exception, a test time of a test tool being timed out, or failure in communication with a board management controller of the server device, and the value of the current of the power supply interface corresponding to the one of the server setting spaces is the null value.

2. The set and removed server device detection system according to claim 1, wherein the testing device periodically obtains the MAC addresses of the network connection interfaces from the rack.

3. The set and removed server device detection system according to claim 1, wherein the testing device displays the test status of one of the server setting space where the server device is set, on a display interface.

4. The set and removed server device detection system according to claim 3, wherein the display interface displays the test statuses of the server setting spaces where the server devices are set, in a table, and each of rows of the table indicates one of the layers of the rack accommodation spaces, and each of data cells in each of the rows indicates one of the server setting spaces.

5. The set and removed server device detection system according to claim 4, wherein the data cell displays the different test statuses of the server device with different presentation effects.

6. A set and removed server device detection method, comprising:
providing a rack having layers of rack accommodation spaces, power supply interfaces and network connection interfaces, wherein each of the layers of rack accommodation spaces comprises server setting spaces, one of the power supply interfaces and one of network connection interfaces are disposed in one of the server setting spaces, and the rack is configured to provide a MAC address of one of the network connection interfaces;
providing a power management system comprising power suppliers, wherein each of the power suppliers is configured to supply power to the power supply interfaces in the server setting spaces in one of the layers of rack accommodation space in the rack, the power management system is configured to provide current to one of the power supply interfaces;
linking a testing device to the rack and the power management system;
obtaining the MAC addresses of the network connection interfaces from the rack, and obtaining values of currents of the power supply interfaces from the power management system, by the testing device,
wherein the testing device is operative to:
determine that a server device is set in one of the server setting spaces when the value of the current of the power supply interface corresponding to the one of the server setting spaces is not a null value and the MAC address of the network connection interface corresponding to the one of the server setting space is not the null value;
establish a test work to test the server device set in the one of the server setting spaces;
determine that the server device is removed from the one of the server setting spaces and delete the test work when a test status of the server device set in the one of the server setting spaces is a successful status, or an error status and the testing device fails to communicate with the board management controller of the server device; and
determine that the server device is removed from the one of the server setting space, end and delete the test work when the test status of the server device set in the one of the server setting space is a test tool exception, a test time of a test tool being timed out, or failure in communication with a board management controller of the server device, and the value of the current of the power supply interface corresponding to the one of the server setting spaces is the null value.

7. The set and removed server device detection method according to claim 6, wherein the testing device periodically obtains the MAC addresses of the network connection interfaces from the rack.

8. The set and removed server device detection method according to claim 6, wherein the testing device displays the test status of one of the server setting space where the server device is set, on a display interface.

9. The set and removed server device detection method according to claim 8, wherein the display interface displays the test statuses of the server setting spaces where the server devices are set, in a table, and each of rows of the table indicates one of the layers of the rack accommodation spaces, and each of data cells in each of the rows indicates one of the server setting spaces.

10. The set and removed server device detection method according to claim 9, wherein the data cell displays the different test statuses of the server device with different presentation effects.
